(19) United States
(12) Patent Application Publication
(10) Pub. No.: US 2011/0315955 A1
(43) Pub. Date: Dec. 29, 2011

(54) LIGHT-EMITTING DIODE AND LIGHT-EMITTING DIODE LAMP

(75) Inventors: Ryouichi Takeuchi, Chichibu-shi (JP); Wataru Nabekura, Chichibu-shi (JP)

(73) Assignee: SHOWA DENKO K.K., Minato-ku, Tokyo (JP)

(21) Appl. No.: 13/148,428

(22) PCT Filed: Jan. 15, 2010
(86) PCT No.: PCT/JP2010/000193

§ 371 Date: Aug. 8, 2011

(30) Foreign Application Priority Data
Feb. 10, 2009 (JP) 2009-028576

(51) Int. Cl. H01L 33/06

(52) U.S. Cl. 257/13; 257/E33.008

(57) ABSTRACT

A light-emitting diode includes a transparent substrate and a compound semiconductor layer that includes a light-emitting unit and is bonded to the transparent substrate. The light-emitting unit includes a light-emitting layer represented by a composition formula (Al_{X}Ga_{1-X})_{Y}In_{1-Y}P (0≦X≦1, 0<Y≦1). A first electrode and a second electrode having a polarity different from that of the first electrode are provided on a main light-emitting surface of the light-emitting diode. The second electrode is formed on the compound semiconductor layer so as to be opposite to the first electrode with a light-emitting layer interposed therebetween. The side surface of the transparent substrate includes a first side surface that is close to the light-emitting layer and is substantially vertical to a light-emitting surface of the light-emitting layer and a second side surface that is distanced away from the light-emitting layer and is inclined with respect to the light-emitting surface. The light-emitting diode further includes a third electrode that is provided on the rear surface of the transparent substrate. In this way, it is possible to provide a light-emitting diode with high light emission efficiency, high productivity in a mounting process, and high brightness.

### TECHNICAL FIELD

The present invention relates to a light-emitting diode and a light-emitting diode lamp.

### BACKGROUND ART

As a light-emitting diode (LED) that emits red, orange, yellow, or yellowish green visible light, a compound semiconductor LED is known which includes a light-emitting layer made of aluminum gallium indium phosphide (composition formula (Al_{X}Ga_{1-X})_{Y}In_{1-Y}P; 0≦X≦1, 0<Y≦1). In the LED, a light-emitting unit including the light-emitting layer made of (Al_{X}Ga_{1-X})_{Y}In_{1-Y}P (0≦X≦1, 0<Y≦1) is optically opaque with respect to light emitted from a general light-emitting layer and is formed on a substrate material that does not have sufficiently high mechanical strength, such as gallium arsenide (GaAs).

Therefore, studies have been conducted in order to obtain a high-brightness visible LED and further improve the mechanical strength of an element. That is, a technique has been proposed which forms a so-called junction-type LED in which an opaque transparent substrate material, such as GaAs, is removed and a support layer made of a transparent material that is capable of transmitting light emitted and has mechanical strength more than the related art is bonded (for example, see PLT 1 to PLT 5).

In addition, a method of changing the shape of an element to improve light emission efficiency has been used in order to obtain a high-brightness visible LED. For example, a technique has been proposed which changes the shape of the side surface to improve brightness (for example, see PLT 6 and PLT 7). Furthermore, a technique has been proposed which improves electrostatic resistance using a high-resistivity layer at the interface of a bonded substrate (for example, see PLT 8).

### Patent Literature

[PLT 1] Japanese Patent No. 3230638

[PLT 2] JP-A-6-302857

[PLT 3] JP-A-2002-246640

[PLT 4] Japanese Patent No. 2588849

[PLT 5] JP-A-2001-57441

[PLT 6] JP-A-2007-173551

[PLT 7] U.S. Pat. No. 6,229,160

[PLT 8] JP-A-2007-19057

### SUMMARY OF THE INVENTION

### Technical Problem

As such, it is possible to provide a high-brightness LED by the transparent substrate junction-type LED or the optimization of the shape of the chip. However, for example, there is a demand for a manufacturing technique capable of improving productivity in a mounting process or stabilizing brightness quality. In addition, there are needs related to the mounting process such as improvement in the electrostatic resistance.

In an element having a structure in which electrodes are formed on the front and rear surfaces of the light-emitting diode, many structures related to the mounting technique have been proposed. However, in a high-brightness element in which two electrodes are provided on the light-emitting surface, the structure of the high-brightness element including electrical characteristics is complicated and an examination of the stability of the electrostatic resistance or a mounting technique has not been sufficiently conducted.

For example, PLT 6 discloses a technique in which the side surface of the substrate includes a first side surface that is close to the light-emitting layer and is substantially vertical to the light-emitting surface of the light-emitting layer and a second side surface that is distanced away from the light-emitting layer and is inclined with respect to the light-emitting surface, in order to obtain high brightness.

However, the area of the bottom of the substrate connected to a package is small and the area of the light-emitting surface is large. Therefore, when a wire is connected to the first or second electrode by wire bonding, the chip is likely to fall. In order to obtain stable connection strength between the light-emitting diode element and the package, there are many restrictions in selecting a die bonding agent or managing the connection conditions.

In the light-emitting diode disclosed in PLT 8, a high-resistivity layer is provided between a light-emitting unit and a conductive substrate to improve electrostatic resistance. However, since the light-emitting diode is electrically connected to the package, it is necessary to use a conductive paste such as silver paste. The conductive paste absorbs a large amount of light. Therefore, in a transparent-substrate-connection-type LED, the conductive paste hinders the emission of light. In particular, for example, when an excessively large amount of silver paste, which is the conductive paste, is used, the silver paste covers the side surface of the transparent substrate. As a result, brightness is significantly reduced. On the other hand, when the amount of conductive paste used is too small, connection strength is insufficient and a LED chip is unstable.

The invention has been made in view of the above-mentioned problems and an object of the invention is to provide a light-emitting diode that includes two electrodes provided on a light-emitting surface and an inclined side surface, is capable of improving productivity in a mounting process while maintaining high light emission efficiency, and prevents a reverse current from flowing to a light-emitting layer when a reverse voltage is applied.

### Solution to the Problem

That is, the invention relates to the following.

According to a first aspect of the invention, a light-emitting diode includes: a transparent substrate; a compound semiconductor layer that includes a pn-junction-type light-emitting unit and is bonded to the transparent substrate; first and second electrodes that are provided on a main light-emitting surface of the light-emitting diode; and a third electrode that is provided on a surface of the transparent substrate opposite to a bonding surface between the transparent substrate and the compound semiconductor layer.

According to a second aspect of the invention, in the light-emitting diode according to the first aspect, the third electrode may be a Schottky electrode.

According to a third aspect of the invention, in the light-emitting diode according to the first or second aspect, the third electrode may include a reflecting layer that has a reflectance of 90% or more with respect to light emitted from the light-emitting surface.

According to a fourth aspect of the invention, in the light-emitting diode according to the third aspect, the reflecting layer may be made of silver, gold, aluminum, platinum, or an alloy including at least one of the materials.

According to a fifth aspect of the invention, in the light-emitting diode according to the third or fourth aspect, the third electrode may include an oxide film that is provided between a surface which comes into contact with the transparent substrate and the reflecting layer.

According to a sixth aspect of the invention, in the light-emitting diode according to the fifth aspect, the oxide film may be a transparent conductive film.

According to a seventh aspect of the invention, in the light-emitting diode according to the sixth aspect, the transparent conductive film may be a transparent conductive film (ITO) made of an indium tin oxide.

According to an eighth aspect of the invention, in the light-emitting diode according to any one of the first to seventh aspects, the third electrode may include a connection layer that is provided on a side opposite to the surface which comes into contact with the transparent substrate.

According to a ninth aspect of the invention, in the light-emitting diode according to the eighth aspect, the connection layer may be made of eutectic metal with a melting point of less than 400° C.

According to a tenth aspect of the invention, in the light-emitting diode according to the eighth or ninth aspect, the third electrode may include a high-melting-point barrier metal that is provided between the reflecting layer and the connection layer and has a melting point of 2000° C. or more.

According to an eleventh aspect of the invention, in the light-emitting diode according to the tenth aspect, the high-melting-point barrier metal may include at least one selected from the group consisting of tungsten, molybdenum, titanium, platinum, chromium, and tantalum.

According to a twelfth aspect of the invention, in the light-emitting diode according to any one of the first to eleventh aspects, the light-emitting unit may include a light-emitting layer that is made of a material represented by a composition formula (Al_{X}Ga_{1-X})_{Y}In_{1-Y}P (0≦X≦1, 0<Y≦1).

According to a thirteenth aspect of the invention, in the light-emitting diode according to any one of the first to twelfth aspects, the first and second electrodes may be ohmic electrodes.

According to a fourteenth aspect of the invention, in the light-emitting diode according to any one of the first to thirteenth aspects, the transparent substrate may be made of GaP.

According to a fifteenth aspect of the invention, in the light-emitting diode according to any one of the first to fourteenth aspects, a side surface of the transparent substrate may include a vertical surface that is close to the compound semiconductor layer and is substantially vertical to the light-emitting surface and an inclined surface that is distanced away from the compound semiconductor layer and is inclined inward with respect to the light-emitting surface.

According to a sixteenth aspect of the invention, the light-emitting diode according to any one of the first to fifteenth aspects may further include a high-resistivity layer that is provided between the compound semiconductor layer and the transparent substrate and has a resistance more than that of the transparent substrate.

According to a seventeenth aspect of the invention, a light-emitting diode lamp includes the light-emitting diode according to any one of the first to sixteenth aspects. The first or second electrode provided above the light-emitting unit of the light-emitting diode and the third electrode are connected to each other so as to have substantially the same potential.

### Advantageous Effects of the Invention

The light-emitting diode of the invention includes the third electrode that is provided on the side opposite to a bonding surface of the transparent substrate to the compound semiconductor layer, in addition to the first and second electrodes provided on the main light-emitting surface. The third electrode is a new electrode with a laminated structure that is capable of obtaining high brightness, electrical connection, and stability in a mounting process. Therefore, it is possible to provide a light-emitting diode that is capable of improving productivity in a mounting process while maintaining high light emission efficiency and prevents a reverse current from flowing to a light-emitting layer when a reverse voltage is applied.

The light-emitting diode lamp according to the invention includes the light-emitting diode, and the first or second electrode provided above the light-emitting unit of the light-emitting diode and the third electrode are connected to each other so as to have substantially the same potential. Therefore, it is possible to provide a light-emitting diode lamp that prevents a reverse current from flowing to a light-emitting layer when a reverse voltage is applied.

### BRIEF DESCRIPTION OF DRAWINGS

FIG. 1 is a plan view illustrating a light-emitting diode lamp using a light-emitting diode according to an embodiment of the invention.

FIG. 2 is a cross-sectional view schematically illustrating a light-emitting diode lamp using a light-emitting diode according to an embodiment of the invention taken along the line A-A′ of FIG. 1.

FIG. 3 is a plan view illustrating a light-emitting diode according to an embodiment of the invention.

FIG. 4 is a cross-sectional view schematically illustrating a light-emitting diode according to an embodiment of the invention taken along the line B-B′ of FIG. 3.

FIG. 5 is a cross-sectional view schematically illustrating a third electrode of a light-emitting diode according to an embodiment of the invention.

FIG. 6 is a cross-sectional view schematically illustrating an epitaxial wafer used in a light-emitting diode according to an embodiment of the invention.

FIG. 7 is a cross-sectional view schematically illustrating a bonded wafer used in a light-emitting diode according to an embodiment of the invention.

### DESCRIPTION OF THE EMBODIMENTS

Hereinafter, a light-emitting diode according to an embodiment of the invention and a light-emitting diode lamp using the light-emitting diode will be described in detail with reference to the accompanying drawings. The following drawings are for ease of understanding of characteristics. Therefore, in some cases, a characteristic portion is enlarged for convenience. For example, the scale and dimensions of each component may be different from the actual scale and dimensions.

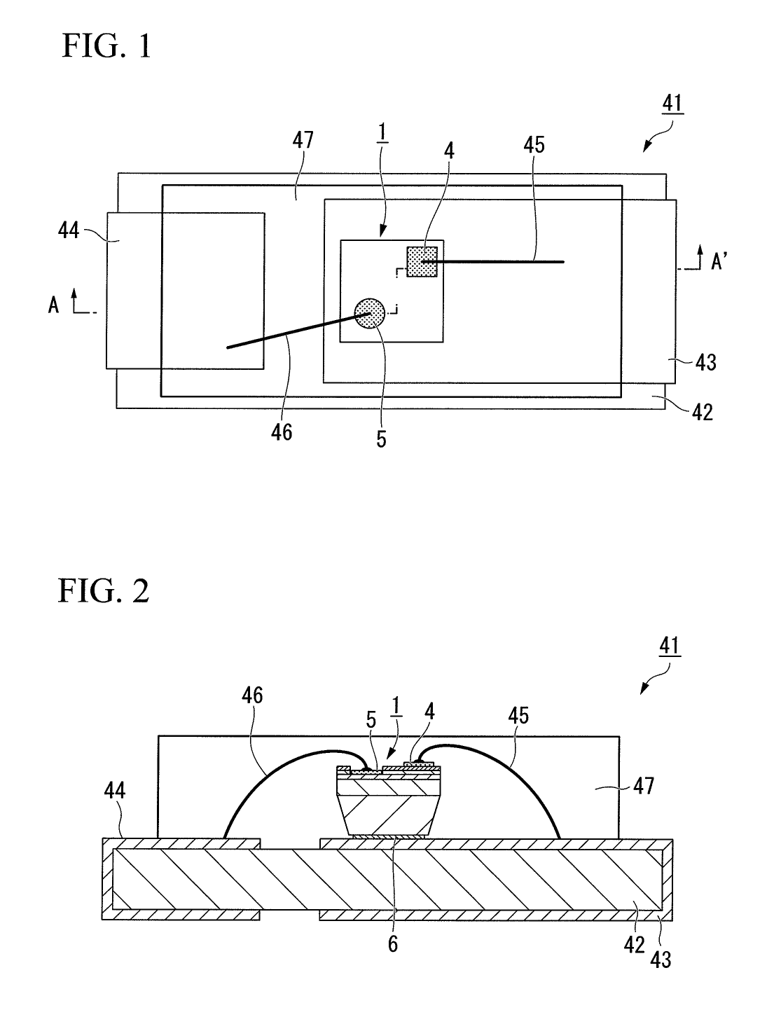

FIGS. 1 and 2 are diagrams illustrating a light-emitting diode lamp using a light-emitting diode according to an embodiment of the invention. FIG. 1 is a plan view and FIG. 2 is a cross-sectional view taken along the line A-A′ of FIG. 1.

As shown in FIGS. 1 and 2, a light-emitting diode lamp 41 using a light-emitting diode 1 according to this embodiment includes one or more light-emitting diodes 1 mounted on the surface of a mounting substrate 42. Specifically, an n electrode terminal 43 and a p electrode terminal 44 are provided on the surface of the mounting substrate 42. An n-type ohmic electrode 4, which is a first electrode of the light-emitting diode 1, and an n electrode terminal 43 of the mounting substrate 42 are connected to each other by a gold wire 45 (wire bonding). A p-type ohmic electrode 5, which is a second electrode of the light-emitting diode 1, and a p electrode terminal 44 of the mounting substrate 42 are connected to each other by a gold wire 46. In addition, as shown in FIG. 2, a third electrode 6 is provided on a surface opposite to the surface of the light-emitting diode 1 on which the n-type and p-type ohmic electrodes 4 and 5 are provided, and the light-emitting diode 1 is connected to the n electrode terminal 43 by the third electrode 6 so as to be fixed to the mounting substrate 42. The n-type ohmic electrode 4 and the third electrode 6 are electrically connected to each other by the n electrode terminal 43 so as to have the same potential or substantially the same potential. The surface of the mounting substrate 42 on which the light-emitting diode 1 is mounted is sealed by a general epoxy resin 47.

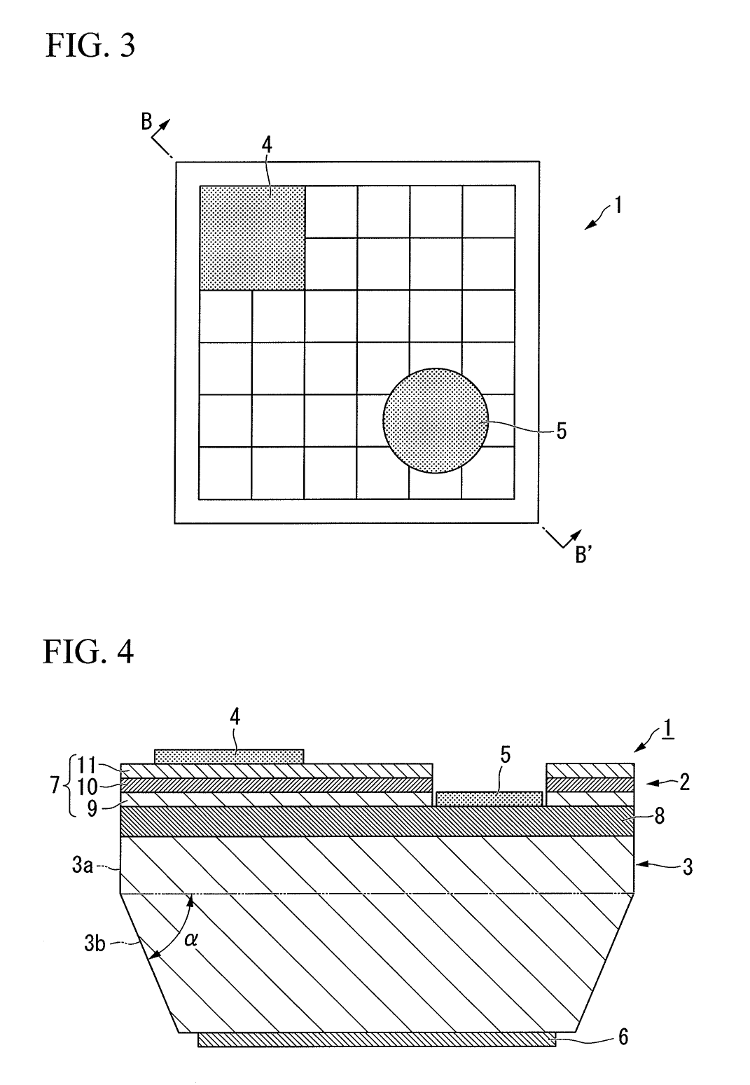

FIGS. 3 and 4 are diagrams illustrating a light-emitting diode according to an embodiment of the invention. FIG. 3 is a plan view and FIG. 4 is a cross-sectional view taken along the line B-B′ of FIG. 3. As shown in FIGS. 3 and 4, in a light-emitting diode 1 according to this embodiment, a compound semiconductor layer 2 including a pn-junction-type light-emitting unit 7 is bonded to a transparent substrate 3. The light-emitting diode 1 has a schematic structure including an n-type ohmic electrode (first electrode) 4 and a p-type ohmic electrode (second electrode) 5 that are provided on a main light-emitting surface and a third electrode 6 that is provided on a surface opposite to a bonding surface of the transparent substrate 3 to the compound semiconductor layer 2. In this embodiment, the main light-emitting surface is a surface opposite to the surface of the light-emitting unit 7 to which the transparent substrate 3 is attached.

The compound semiconductor layer 2 is not particularly limited as long as it includes the pn-junction-type light-emitting unit 7. The light-emitting unit 7 is a compound semiconductor laminated structure including a light-emitting layer 10 that is made of (Al_{X}Ga_{1-X})_{Y}In_{1-Y}P (0≦X≦1, 0<Y≦1). Specifically, for example, the light-emitting unit 7 is formed by sequentially laminating at least a p-type lower clad layer 9, the light-emitting layer 10, and an n-type upper clad layer 11 on a Mg-doped p-type GaP layer 8 with a carrier concentration of 1×10¹⁸ cm ⁻³ to 8×10¹⁸ cm⁻³ and a thickness of 5 μm to 15 μm.

The light-emitting layer 10 may be made of undoped n-type or p-type (Al_{X}Ga_{1-X})_{Y}In_{1-Y}P (0≦X≦1, 0<Y≦1). It is preferable that the light-emitting layer 10 have a thickness of 0.1 μm to 2 μm and a carrier concentration of less than 3×10¹⁷ cm⁻³. The light-emitting layer 10 may have any one of a double heterostructure, a single quantum well (SQW) structure, and a multi-quantum well (MQW) structure. However, it is preferable that the light-emitting layer 10 have the MQW structure in order to emit good monochromatic light. In addition, the composition of (Al_{X}Ga_{1-X})_{Y}In_{1-Y}P (0≦X≦1, 0<Y≦1) forming a barrier layer and a well layer of the quantum well (QW) structure may be determined such that a quantum level capable of obtaining a desired emission wavelength is formed in the well layer.

It is preferable that the light-emitting unit 7 have a so-called double hetero (DH) structure including the light-emitting layer 10, and the lower clad layer 9, and the upper clad layer 11 that are provided on the lower and upper sides of the light-emitting layer 10 so as to be opposite to each other in order to “confine” carriers for radiation recombination and emitted light in the light-emitting layer 10, in order to emit high-intensity light. The lower clad layer 9 and the upper clad layer 11 are preferably made of a semiconductor material with a forbidden bandwidth wider than that of (Al_{X}Ga_{1-X})_{Y}In_{1-Y}P (0≦X≦1, 0<Y≦1) forming the light-emitting layer 10.

For example, it is preferable that a Mg-doped semiconductor material made of p-type (Al_{X}Ga_{1-X})_{Y}In_{1-Y}P (0≦X≦1, 0<Y≦1) with a carrier concentration of 1×10¹⁷ cm⁻³ to 1×10¹⁸ cm⁻³ and a thickness of 0.5 μm to 2 μm be used as the lower clad layer 9. It is preferable that a Si-doped semiconductor material made of n-type (Al_{X}Ga_{1-X})_{Y}In_{1-Y}P (0≦X≦1, 0<Y≦1) with a carrier concentration of 2×10¹⁷ cm⁻³ to 2×10¹⁸ cm ⁻³ and a thickness of 0.5 μm to 5 μm be used as the upper clad layer 11.

In addition, intermediate layers that slowly change band discontinuity between the light-emitting layer 10 and the lower and upper clad layers 9 and 11 may be provided between the light-emitting layer 10 and the lower and upper clad layers 9 and 11. In this case, the intermediate layer may be made of a semiconductor material with an intermediate forbidden bandwidth between those of the light-emitting layer 10 and the lower and upper clad layers 9 and 11. Similarly, this can be applied to a case in which the light-emitting layer 10 is made of, for example, AlₓGa₍₁₋ₓ₎As.

A known layer structure including a contact layer for reducing the contact resistance of an ohmic electrode, a current diffusion layer for diffusing an element driving current on the entire plane of a light-emitting unit, and a current blocking layer or a current confining layer for limiting the region in which the element driving current flows may be provided on the structural layers of the light-emitting unit 7.

As shown in FIG. 4, the transparent substrate 3 is bonded to a p-type GaP layer 8 of the compound semiconductor layer 2. The transparent substrate 3 is made of an optically transparent and conductive material that has sufficient strength to mechanically support the light-emitting unit 7 and a sufficiently wide forbidden bandwidth to transmit light emitted from the light-emitting unit 7. For example, the transparent substrate 3 may be made of gallium phosphide (GaP), aluminum gallium arsenide (AlGaAs), a group III-V compound semiconductor crystal, such as gallium nitride (GaN), a group II-VI compound semiconductor crystal, such as zinc sulfide (ZnS) or zinc selenide (ZnSe), or a group IV semiconductor crystal, such as hexagonal or cubic silicon carbide (SiC).

It is preferable that the transparent substrate 3 have a thickness of, for example, about 50 μm or more in order to support the light-emitting unit 7 with mechanically sufficient strength. In addition, it is preferable that the thickness of the transparent substrate 3 be equal to or less than about 300 μm in order to facilitate the mechanical processing of the transparent substrate 3 after the transparent substrate 3 is bonded to the compound semiconductor layer 2. That is, in the light-emitting diode 1 according to this embodiment that includes the light-emitting layer 10 made of (Al_{X}Ga_{1-X})_{Y}In_{1-Y}P (0≦X≦1, 0<Y≦1), it is most preferable that the transparent substrate 3 be an n-type GaP substrate with a thickness that is equal to or more than about 50 μm and equal to or less than 300 μm.

As shown in FIG. 4, the side surface of the transparent substrate 3 includes a vertical surface 3a that is close to the compound semiconductor layer 2 and is substantially vertical to the main light-emitting surface and an inclined surface 3b that is distanced away from the compound semiconductor layer 2 and is inclined with respect to the main light-emitting surface. In this way, it is possible to extract light emitted from the light-emitting layer 10 to the transparent substrate 3 to the outside. In addition, a portion of the light emitted from the light-emitting layer 10 to the transparent substrate 3 can be reflected from the vertical surface 3a and then extracted from the inclined surface 3b. The light reflected from the inclined surface 3b can be extracted from the vertical surface 3a. As such, it is possible to improve light emission efficiency with the synergistic effect of the vertical surface 3a and the inclined surface 3b.

In this embodiment, as shown in FIG. 4, it is preferable that the angle α formed between the inclined surface 3b and a plane parallel to the light-emitting surface be in the range of 55 degrees to 80 degrees. This range makes it possible to effectively extract light reflected from the bottom of the transparent substrate 3 to the outside.

It is preferable that the width of the vertical surface 3a (in the thickness direction) be in the range of 30 μm to 100 μm. When the range of the vertical surface 3a is in the above-mentioned range, the vertical surface 3a can effectively return the light reflected from the bottom of the transparent substrate 3 to the light-emitting surface and it is possible to emit the light from the light-emitting surface. Therefore, it is possible to improve the light emission efficiency of the light-emitting diode 1.

It is preferable that the inclined surface 3b of the transparent substrate 3 be roughened. When the inclined surface 3b is roughened, the effect of improving light emission efficiency is obtained by the inclined surface 3b. That is, when the inclined surface 3b is roughened, total reflection from the inclined surface 3b is prevented and it is possible to improve light emission efficiency.

In some cases, a bonding interface between the compound semiconductor layer 2 and the transparent substrate 3 is a high-resistivity layer. That is, in some cases, a high-resistivity layer (not shown) is provided between the compound semiconductor layer 2 and the transparent substrate 3. The high-resistivity layer has a resistance value greater than that of the transparent substrate 3. The high-resistivity layer has a function of reducing a reverse current from the p-type GaP layer 8 of the compound semiconductor layer 2 to the transparent substrate 3. In addition, a bonding structure that has resistance to a reverse voltage applied from the transparent substrate 3 to the p-type GaP layer 8 is constructed. However, it is preferable that the breakdown voltage thereof be less than the reverse voltage of the pn-junction-type light-emitting unit 7.

The n-type ohmic electrode 4 and the p-type ohmic electrode 5 are low-resistance ohmic contact electrodes that are provided on the main light-emitting surface of the light-emitting diode 1. The n-type ohmic electrode 4 is provided on the upper clad layer 11 and may be made of an alloy, such as AuGe or Ni alloy/Pt/Au. As shown in FIG. 4, the p-type ohmic electrode 5 is formed on the surface of an exposed portion of the p-type GaP layer 8 and may be made of an alloy such as AuBe/Au.

In the light-emitting diode 1 according to this embodiment, it is preferable that the light-emitting unit 7 include the p-type GaP layer 8 and the p-type ohmic electrode 5 serving as the second electrode be formed on the p-type GaP layer 8. According to this structure, the effect of reducing an operating voltage is obtained. When the p-type ohmic electrode 5 is formed on the p-type GaP layer 8, a good ohmic contact is obtained. Therefore, it is possible to reduce the operating voltage.

In this embodiment, it is preferable that the polarity of the first electrode be n and the polarity of the second electrode is p. According to this structure, it is possible to increase the brightness of the light-emitting diode 1. When the first electrode is a p-type, current diffusion deteriorates, which causes a reduction in the brightness. In contrast, when the first electrode is an n-type, current diffusion is improved and it is possible to increase the brightness of the light-emitting diode 1.

In the light-emitting diode 1 according to this embodiment, as shown in FIG. 3, it is preferable that the n-type ohmic electrode 4 and the p-type ohmic electrode 5 be diagonally arranged. In addition, it is preferable that the p-type ohmic electrode 5 be surrounded by the compound semiconductor layer 2. According to this structure, the effect of reducing the operating voltage is obtained. When the p-type ohmic electrode 5 is surrounded by the n-type ohmic electrode 4, it is easy for a current to flow in all directions. As a result, the operating voltage is reduced.

In the light-emitting diode 1 according to this embodiment, as shown in FIG. 3, it is preferable that the n-type ohmic electrode 4 be formed in a net shape, such as a honeycomb shape or a lattice shape. According to this structure, the effect of improving reliability is obtained. When the n-type ohmic electrode 4 is formed in a lattice shape, it is possible to inject a uniform current to the light-emitting layer 10. As a result, the effect of improving reliability is obtained. In the light-emitting diode 1 according to this embodiment, it is preferable that the n-type ohmic electrode 4 include a pad-shaped electrode (pad electrode) and a line-shaped electrode (linear electrode) with a width equal to or less than 10 μm. According to this structure, it is possible to improve brightness. When the width of the linear electrode is reduced, it is possible to increase the area of an aperture in the light-emitting surface and thus improve brightness.

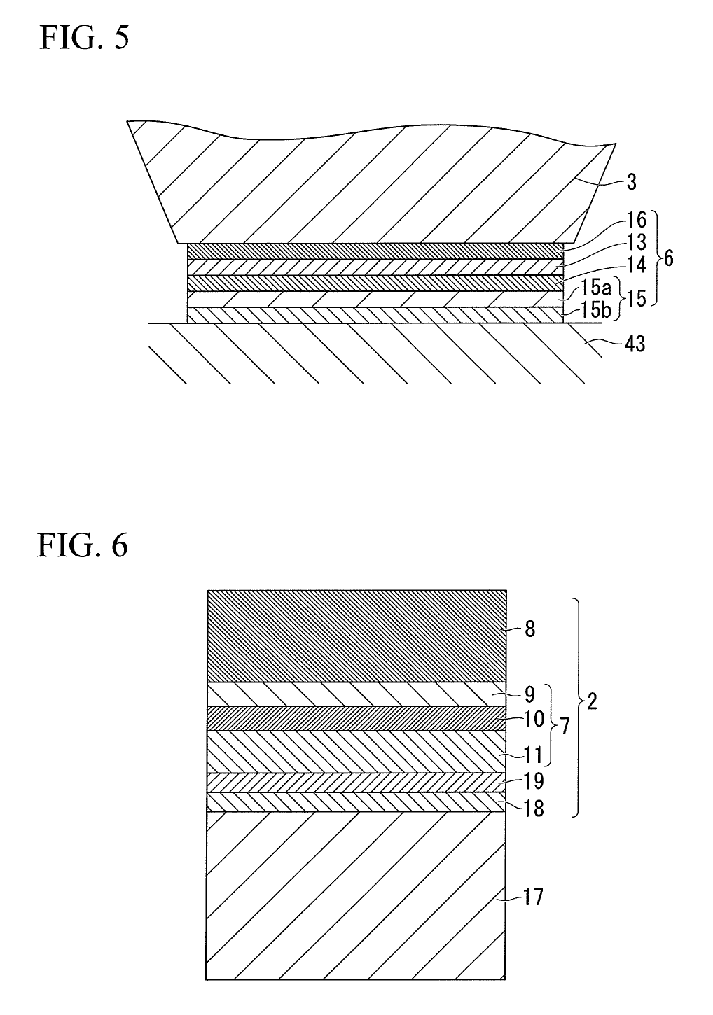

FIG. 5 is a cross-sectional view illustrating the third electrode 6 of the light-emitting diode 1 according to this embodiment. As shown in FIGS. 4 and 5, the third electrode 6 is formed on the lower surface of the transparent substrate 3 and has a laminated structure capable of achieving high brightness, electrical connection, and stability in a mounting process. Specifically, the third electrode 6 has a schematic structure in which at least a reflecting layer 13, a bather layer 14, and a connection layer 15 are formed from the bottom of the transparent substrate 3. In addition, the third electrode 6 may be an ohmic electrode or a Schottky electrode. When an ohmic electrode is formed on the lower surface of the transparent substrate 3, it absorbs light emitted from the light-emitting layer 10. Therefore, it is preferable that the third electrode 6 be a Schottky electrode. The thickness of the third electrode 6 is not particularly limited. However, the thickness of the third electrode 6 is preferably in the range of 0.2 μm to 5 μm, more preferably in the range of 1 μm to 3 μm, and most preferably in the range of 1.5 μm to 2.5 μm. When the thickness of the third electrode 6 is less than 0.2 μm, an advanced thickness control technique is needed, which is not preferable. When the thickness of the third electrode 6 is more than 5 μm, it is difficult to perform patterning and costs increase, which is not preferable. When the thickness of the third electrode 6 is in the above-mentioned range, it is possible to stabilize quality and reduce costs, which is preferable.

The reflecting layer 13 is provided in order to increase the brightness of the light-emitting diode 1, that is, in order to extract light emitted from the light-emitting layer 10 to the transparent substrate 3 to the outside with high efficiency. It is preferable that the reflectance of the reflecting layer 13 with respect to light emitted from the light-emitting surface be equal to or more than 90%. In addition, metal with high reflectance may be applied to the reflecting layer 13. Specifically, for example, the reflecting layer 13 is made of silver, gold, aluminum, platinum, and alloys of these metal materials. The thickness of the reflecting layer 13 is not particularly limited. However, the thickness of the reflecting layer 13 is preferably in the range of 0.02 μm to 2 μm, more preferably in the range of 0.05 μm to 1 μm, and most preferably in the range of 0.05 μm to 0.5 μm. When the thickness of the reflecting layer 13 is less than 0.02 μm, light is likely to pass through the reflecting layer 13 according to the kind of metal and the reflectance of the reflecting layer 13 is likely to be reduced, which is not preferable. When the thickness of the reflecting layer 13 is more than 2 μm, stress and costs increase, which is not preferable. When the thickness of the reflecting layer 13 is in the above-mentioned range, reflectance increases and costs are reduced, which is preferable.

As shown in FIG. 5, in the third electrode 6, it is preferable that an oxide film 16 be inserted into a contact surface between the transparent substrate 3 and the reflecting layer 13. The oxide film 16 is provided in order to prevent the diffusion and reaction between a metal material forming the reflecting layer 13 and the transparent substrate 3, which is a semiconductor substrate. When the oxide film 16 is inserted between the transparent substrate 3 and the reflecting layer 13, it is possible to prevent a reduction in the reflectance of the reflecting layer 13.

Known materials, for example, transparent conductive films, such as an indium tin oxide (ITO) film and an indium zinc oxide (IZO) film, insulating films, such as a silicon oxide (SiO₂) film and a silicon nitride (SiN) film, and a partial metal film for ensuring electrical contact, and combinations thereof may be used as the oxide film 16. However, it is preferable to use the transparent conductive film as the oxide film 16 in order to effectively extract light emitted from the light-emitting layer 10 to the transparent substrate 3 to the outside and it is more preferable to use the ITO film. The thickness of the oxide film 16 is not particularly limited. However, the thickness of the oxide film 16 is preferably in the range of 0.02 μm to 1 μm, more preferably in the range of 0.05 μm to 0.5 μm, and most preferably in the range of 0.1 μm to 0.2 μm. When the thickness of the oxide film 16 is less than 0.02 μm, the diffusion between the metal material forming the reflecting layer and the transparent substrate is not sufficiently prevented, which is not preferable. When the thickness of the oxide film 16 is more than 1 μm, the stress of the film increases and cracking is likely to occur, which is not preferable. When the thickness of the oxide film 16 is in the above-mentioned range, the quality of the film is stabilized, which is preferable.

As shown in FIG. 5, the barrier layer 14 is provided between the reflecting layer 13 and the connection layer 15. The barrier layer 14 has a function of preventing the diffusion between the metal material forming the reflecting layer 13 and a metal material forming the connection layer 15 and thus preventing a reduction in the reflectance of the reflecting layer 13. The barrier layer 14 is made of a high-melting-point barrier metal material with a melting point of 2000° C. or more. For example, high-melting-point metal materials, such as tungsten, molybdenum, titanium, platinum, chromium, and tantalum, may be used as the high-melting point barrier metal material, and it is preferable that the high-melting-point barrier metal material include at least one of these metal materials. The thickness of the barrier layer 14 is not particularly limited. However, the thickness of the barrier layer 14 is preferably in the range of 0.05 μm to 0.5 μm, more preferably in the range of 0.08 μm to 0.2 μm, and most preferably in the range of 0.1 μm to 0.15 μm. When the thickness of the bather layer 14 is less than 0.05 μm, a sufficient barrier function is not obtained, which is not preferable. When the thickness of the barrier layer 14 is more than 0.5 μm, stress or the process temperature increases, which is not preferable. When the thickness of the bather layer 14 is in the above-mentioned range, it is possible to obtain a stable quality, which is preferable.

As shown in FIG. 5, the connection layer 15 is provided on the side opposite to the interface between the transparent substrate 3 and the oxide film 16 of the third electrode 6, that is, on the side where it faces the n electrode terminal 43 provided on the surface of the mounting substrate 42. The connection layer 15 is melted and connected to the mounting substrate 42 when the light-emitting diode 1 is mounted. The connection layer 15 includes a layer (low-melting-point metal layer) 15b made of a metal material with a low melting point. The low-melting-point metal layer 15b may be made of In, Sn metal, and known solder materials. It is preferable that the low-melting-point metal layer 15b be made of eutectic metal with a low melting point. Examples of the eutectic metal with a low melting point include AuSn, AuGe, and AuSi. In particular, Au-based eutectic metal is preferable since a stable quality is obtained. It is particularly preferable that Au layers be formed before and after the connection layer. In this case, the composition is changed after melting and the melting point increases. Therefore, heat resistance in the mounting process is improved.

However, in the light-emitting diode according to the related art, silver (Ag) paste is used to mount the light-emitting diode on the mounting substrate. The silver paste has high reflectance. Therefore, when the silver paste is used to mount the light-emitting diode on the mounting substrate, a high-brightness light-emitting diode lamp is obtained. However, since the silver paste has a low connection strength, a large amount of silver paste is needed in order to reliably bond the mounting substrate. In particular, when the transparent substrate 3 including the inclined surface 3b is bonded as in the light-emitting diode 1 according to this embodiment, a large amount of silver paste is needed in order to obtain stable connection, and the silver paste covers the inclined surface 3b of the transparent substrate 3. As a result, the brightness of the light-emitting diode is reduced.

In contrast, in the light-emitting diode according to this embodiment, the connection layer 15 of the third electrode 6 may be used to mount the light-emitting diode on the mounting substrate. As described above, in the connection layer 15, since the eutectic metal is used to form the low-melting-point metal layer 15b, it is possible to achieve strong connection with a small amount of paste using eutectic metal die bonding. Therefore, the inclined surface 3b of the transparent substrate 3 is not covered by the connection layer 15 and the reflecting layer 13 of the third electrode 6 also has a function of improving brightness. As a result, it is possible to improve the brightness and connection strength of the light-emitting diode 1.

The lower limit of the melting point of the connection layer 15 (low-melting-point metal layer 15b) is preferably equal to or more than 150° C., more preferably equal to or more than 200° C., and most preferably equal to or more than 250° C. The upper limit of the melting point is preferably less than 400° C., more preferably less than 350° C., and most preferably less than 300° C. When the melting point is less than 150° C., the connection layer is melted during the soldering of components other than the light-emitting diode 1, which is not preferable. When the melting point is equal to or more than 400° C., the package material is likely to be modified, which is not preferable.

As shown in FIG. 5, the connection layer 15 may include a layer 15a that is made of gold (Au) and is provided between the barrier layer 14 and the low-melting-point metal layer 15b. When the layer (gold layer) 15a made of gold is provided, it is possible to prevent the oxidation of the low-melting-point metal layer 15b. Therefore, it is possible to improve the stability of a die bonding process of mounting the light-emitting diode 1 on the mounting substrate 42.

The thickness of the connection layer 15 is not particularly limited. However, the thickness of the connection layer 15 is preferably in the range of 0.2 μm to 3 μm, more preferably in the range of 0.5 μm to 2 μm, and most preferably in the range of 0.8 μm to 1.5 μm. When the thickness of the connection layer 15 is less than 0.2 μm, bonding strength is likely to be insufficient, which is not preferable. When the thickness of the connection layer 15 is more than 3 μm, costs increase, which is not preferable. When the thickness of the connection layer 15 is in the above-mentioned range, stable connection strength is obtained, which is preferable.

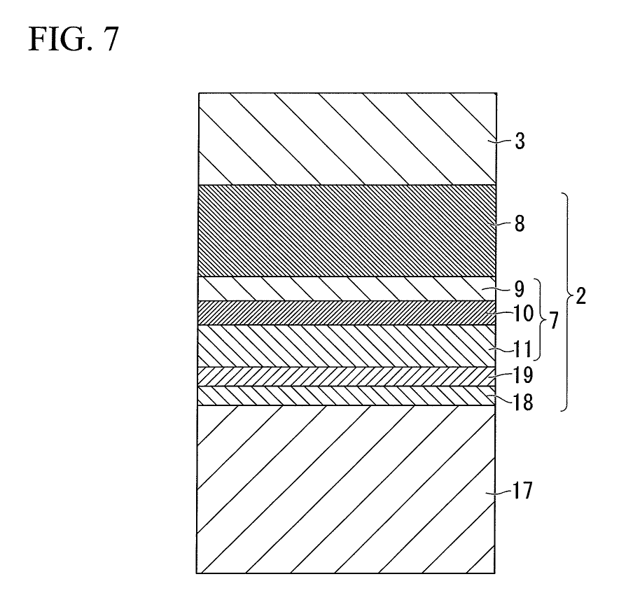

Next, a method of manufacturing the light-emitting diode 1 according to this embodiment and a method of manufacturing a light-emitting diode lamp 41 using the light-emitting diode 1 will be described. FIG. 6 is a cross-sectional view illustrating an epitaxial wafer used in the light-emitting diode 1 according to this embodiment. FIG. 7 is a cross-sectional view illustrating a bonded wafer used in the light-emitting diode 1 according to this embodiment.

### (Process of Forming Compound Semiconductor Layer)

First, as shown in FIG. 6, a compound semiconductor layer 2 is manufactured. The compound semiconductor layer 2 is manufactured by sequentially laminating a Si-doped n-type GaAs buffer layer 18, an etching stop layer (not shown), a Si-doped n-type AlGaInP contact layer 19, an n-type upper clad layer 11, a light-emitting layer 10, a p-type lower clad layer 9, and a Mg doped p-type GaP layer 8 on a semiconductor substrate 17 that is made of, for example, a GaAs single crystal. The buffer layer (buffer) 18 is provided in order to reduce the lattice mismatching between the semiconductor substrate 17 and the structural layers of the light-emitting unit 7. The etching stop layer is provided for selective etching.

Specifically, each layer of the compound semiconductor layer 2 may be epitaxially grown on the GaAs substrate 17 by a reduced-pressure metal-organic chemical vapor deposition method (MOCVD method) using, for example, trimethylaluminum ((CH₃)₃Al), trimethylgallium ((CH₃)₃Ga), and trimethylindium ((CH₃)₃In) as a raw material of a group III element. For example, biscyclopentadienyl magnesium (bis-(C₅H₅)₂Mg) may be used as a Mg-doped raw material. For example, disilane (Si₂H₆) may be used as a Si-doped raw material. For example, phosphine (PH₃) or arsine (AsH₃) may be used as the raw material of the group V element. For the growth temperature of each layer, the growth temperature of the p-type GaP layer 8 may be 750° C. and the growth temperature of the other layers may be 730° C. The carrier concentration and thickness of each layer may be appropriately selected.

### (Process of Bonding Transparent Substrate)

Next, the compound semiconductor layer 2 and the transparent substrate 3 are bonded to each other. During the bonding between the compound semiconductor layer 2 and the transparent substrate 3, first, the surface of the p-type GaP layer 8 of the compound semiconductor layer 2 is polished into a mirror surface. Then, the transparent substrate 3 to be attached to the mirror-polished surface of the p-type GaP layer 8 is prepared. The surface of the transparent substrate 3 is polished into a mirror surface before the transparent substrate 3 is bonded to the p-type GaP layer 8.

Then, the compound semiconductor layer 2 and the transparent substrate 3 are carried into a general semiconductor material attachment apparatus. Then, electrons collide with the two mirror-polished surfaces in vacuum and neutral Ar beams are emitted to the two mirror-polished surfaces. Then, the two surfaces overlap each other in the attachment apparatus in vacuum and a load is applied to the two surfaces. In this way, it is possible to bond the compound semiconductor layer and the transparent substrate at room temperature (see FIG. 7).

### (Process of Forming First and Second Electrodes)

Next, the n-type ohmic electrode 4, which is the first electrode, and the p-type ohmic electrode 5, which is the second electrode, are formed. In the formation of the n-type ohmic electrode 4 and the p-type ohmic electrode 5, first, the semiconductor substrate 17 made of GaAs and the buffer layer 18 are selectively removed from the compound semiconductor layer 2 bonded to the transparent substrate 3 by an ammonia-based etchant. Then, the n-type ohmic electrode 4 is formed on the surface of the exposed contact layer 19. Specifically, for example, an AuGe film and a Ni alloy/Pt/Au are formed with an arbitrary thickness by a vacuum deposition method and are then patterned by a general photolithography method, thereby forming the n-type ohmic electrode 4.

Then, the contact layer 19, the upper clad layer 11, the light-emitting layer 10, and the lower clad layer 9 are selectively removed to expose the p-type GaP layer 8 and the p-type ohmic electrode 5 is formed on the surface of the exposed p-type GaP layer 8. Specifically, for example, an AuBe/Au film is formed with an arbitrary thickness by the vacuum deposition method and is then patterned by the general photolithography method, thereby forming the p-type ohmic electrode 5. Then, a heat treatment is performed under the conditions of, for example, a temperature of 450° C. and a processing time of 10 minutes, thereby making an alloy. In this way, it is possible to form the low-resistance n-type ohmic electrode 4 and p-type ohmic electrode 5.

### (Process of Forming Third Electrode)

Next, the third electrode 6 is formed on a surface of the transparent substrate 3 opposite to the bonding surface to the compound semiconductor layer 2.

In the formation of the third electrode 6, specifically, for example, an ITO film, which is a transparent conductive film, serving as the oxide film 16 is formed with a thickness of 0.1 μm on the surface of the transparent substrate 3 by a sputtering method, and a silver alloy film is formed thereon with a thickness of 0.1 μm, thereby forming the reflecting layer 13. Then, for example, a tungsten film serving as the barrier layer 14 is formed with a thickness of the 0.1 μm on the reflecting layer 13. Then, an Au film with a thickness of 0.5 μm, an AuSn (eutectic alloy: melting point 283° C.) film with a thickness of 1 μm, and an Au film with a thickness of 0.1 μm are sequentially formed on the barrier layer 14, thereby forming the connection layer 15. Then, the layers are patterned in an arbitrary shape by a general photolithography method, thereby forming the third electrode 6. A Schottky contact with low light absorption is formed between the transparent substrate 3 and the third electrode 6.

### (Process of Processing Transparent Substrate)

Next, the transparent substrate 3 is processed. In the processing of the transparent substrate 3, first, a surface of the transparent substrate 3 on which the third electrode 6 is not formed is cut in a V-shape. In this case, the internal surface of the V-shaped groove close to the third electrode 6 is the inclined surface 3b that is inclined at an angle α with respect to the plane parallel to the light-emitting surface. Then, the transparent substrate 3 is diced into chips at a predetermined interval from the side of the compound semiconductor layer 2. The vertical surface 3a of the transparent substrate 3 is formed by dicing when the transparent substrate 3 is cut into chips.

A method of forming the inclined surface 3b is not particularly limited. For example, the methods according to the related art, such as a wet etching method, a dry etching method, a scribing method, and a laser processing method, may be combined with each other. It is most preferable to use a dicing method with high shape controllability and high productivity. The use of the dicing method makes it possible to improve manufacturing yield.

A method of forming the vertical surface 3a is not particularly limited. It is preferable that the vertical surface 3a be formed by a scribing/breaking method or a dicing method. The use of the scribing/breaking method makes it possible to reduce manufacturing costs. That is, it is not necessary to provide a cutting margin when the substrate is divided into chips and it is possible to manufacture a large number of light-emitting diodes. Therefore, it is possible to reduce manufacturing costs. In the dicing method, the emission efficiency of light from the vertical surface 3a is improved and it is possible to obtain high brightness.

Finally, a fractured layer and contamination caused by dicing are removed by etching using a mixture of sulfuric acid and hydrogen peroxide. In this way, the light-emitting diode 1 is manufactured.

### (Process of Mounting Light-Emitting Diode)

Next, a predetermined number of light-emitting diodes 1 are mounted on the surface of the mounting substrate 42. In the mounting of the light-emitting diode 1, first, the light-emitting diode 1 is positioned relative to the mounting substrate 42 and the light-emitting diode 1 is arranged at a predetermined position on the surface of the mounting substrate 42. Then, the connection layer 15 of the third electrode 6 is bonded to the n electrode terminal 43 provided on the surface of the mounting substrate 42 by eutectic metal (eutectic metal die bonding). In this way, the light-emitting diode 1 is fixed to the surface of the mounting substrate 42. Then, the n-type ohmic electrode 4 of the light-emitting diode 1 is connected to the n electrode terminal 43 of the mounting substrate 42 by the gold wire 45 (wire bonding). Then, the p-type ohmic electrode 5 of the light-emitting diode 1 is connected to the p electrode terminal 44 of the mounting substrate 42 by the gold wire 46. Finally, the surface of the mounting substrate 42 on which the light-emitting diode 1 is mounted is sealed by the general epoxy resin 47. In this way, the light-emitting diode lamp 41 using the light-emitting diode 1 is manufactured.

Next, a case in which a voltage is applied to the n electrode terminal 43 and the p electrode terminal 44 in the light-emitting diode lamp 41 having the above-mentioned structure will be described.

First, a case in which a forward voltage is applied to the light-emitting diode lamp 41 will be described.

When the forward voltage is applied, first, a forward current flows from the p-type electrode terminal 44 connected to the anode to the p-type ohmic electrode 5 through the gold wire 46. Then, the forward current sequentially flows from the p-type ohmic electrode 5 to the p-type GaP layer 8, the lower clad layer 9, the light-emitting layer 10, the upper clad layer 11, and the n-type ohmic electrode 4. Then, the forward current flows from the n-type ohmic electrode 4 to the n-type electrode terminal 43 connected to the cathode through the gold wire 45. When a high-resistivity layer is provided in the light-emitting diode 1, the forward current does not flow from the p-type GaP layer 8 to the transparent substrate 3, which is an n-type GaP substrate. As such, when the forward current flows, light is emitted from the light-emitting layer 10. The light emitted from the light-emitting layer 10 is emitted from the main light-emitting surface. The light emitted from the light-emitting layer 10 to the transparent substrate 3 is reflected by the shape of the transparent substrate 3 and the function of the reflecting layer 13 of the third electrode 6 and is emitted from the light-emitting surface. Therefore, it is possible to improve the brightness of the light-emitting diode lamp 41 (light-emitting diode 1) (see FIGS. 2 and 4).

Next, a case in which a reverse voltage is applied to the light-emitting diode lamp 41 will be described.

When the reverse voltage is applied, a reverse current flows from the n-type electrode terminal 43 to the p-type electrode terminal 44. However, in the light-emitting diode lamp according to the related art without the third electrode 6, the reverse current generated when the reverse voltage is applied inadvertently flows to the light-emitting unit with a high reverse voltage in the pn junction portion through the n-type ohmic electrode provided above the light-emitting unit, which may cause damage to the light-emitting unit of the light-emitting diode. In contrast, according to the light-emitting diode lamp 41 including the light-emitting diode 1 according to this embodiment, the third electrode 6 and the n-type ohmic electrode 4 are connected to each other so as to have substantially the same position and a breakdown voltage from the transparent substrate 3 to the p-type GaP layer 8 is less than the reverse voltage of the pn-junction-type light-emitting unit 7. In this way, the reverse current generated when the reverse voltage is applied inadvertently flows to a bonding region with a low breakdown voltage between the transparent substrate 3 and the p-type GaP layer 8 through the third electrode 6 rather than flowing to the light-emitting unit 7 with a high reverse voltage in the pn junction portion through the n-type ohmic electrode provided above the light-emitting unit 7. Therefore, the reverse current can flow to the p-type ohmic electrode 5 without passing through the light-emitting unit 7. As a result, it is possible to prevent damage to the light-emitting unit 7 of the light-emitting diode 1 caused by the flow of a reverse overcurrent.

### EXAMPLES

Next, the effect of the invention will be described in detail using examples. The invention is not limited to the examples.

### Example 1

In this example, an example in which a light-emitting diode according to the invention is manufactured will be described in detail. The light-emitting diode manufactured in this example is a red light-emitting diode having an AlGaInP light-emitting unit. In Example 1 of the invention, a case in which an epitaxial laminated structure (compound semiconductor layer) provided on a GaAs substrate is bonded to a GaP substrate to manufacture a light-emitting diode will be described in detail.

The light-emitting diode according to Example 1, first was manufactured using an epitaxial wafer including semiconductor layers sequentially laminated on a semiconductor substrate which had a surface inclined at an angle of 15° with respect to the Si doped n-type (100) plane and was made of a GaAs single crystal. The laminated semiconductor layers were a Si-doped n-type GaAs buffer layer, a Si-doped n-type (Al_{0.5}Ga_{0.5})_{0.5}In_{0.5}P contact layer, a Si-doped n-type (Al_{0.7}Ga_{0.3})_{0.5}In_{0.5}P upper clad layer, an undoped light-emitting layer including 20 pairs of (Al_{0.2}Ga_{0.8})_{0.5}In_{0.5}P/(Al_{0.7}Ga_{0.3})_{0.5}In_{0.5}P, a Mg-doped p-type (Al_{0.7}Ga_{0.3})_{0.5}In_{0.5}P lower clad layer, a thin (Al_{0.5}Ga_{0.5})_{0.5}In_{0.5}P intermediate layer, and a Mg-doped p-type GaP layer.

In this example, each layer of the semiconductor layer was formed on the GaAs substrate by a reduced-pressure metal-organic chemical vapor deposition method (MOCVD method) using trimethylaluminum ((CH₃)₃Al), trimethylgallium ((CH₃)₃Ga) and trimethylindium ((CH₃)₃In) as a raw material of a group III element, thereby forming an epitaxial wafer. Biscyclopentadienyl magnesium (bis-(C₅H₅)₂Mg) was used as a Mg-doped raw material. Silane (Si₂H₆) may be used as a Si-doped raw material. Phosphine (PH₃) or arsine (AsH₃) was used as a raw material of a group V element. The GaP layer was grown at a temperature of 750° C. and the other semiconductor layers were grown at a temperature of 730° C.

The carrier concentration of the GaAs buffer layer was about 2×10¹⁸ cm⁻³ and the thickness thereof was about 0.2 μm. The contact layer was made of (Al_{0.5}Ga_{0.5})_{0.5}In_{0.5}P and had a carrier concentration of about 2×10¹⁸ cm⁻³ and a thickness of about 1.5 μm. The carrier concentration of the upper clad layer was about 8×10¹⁷ cm⁻³ and the thickness thereof was about 1 μm. The light-emitting layer was not doped with impurities and had a thickness of 0.8 μm. The carrier concentration of the lower clad layer was about 2×10¹⁷ cm⁻³ and the thickness thereof was 1 μm. The carrier concentration of the p-type GaP layer was about 3×10¹⁸ cm⁻³ and the thickness thereof was 9 μm.

Then, a region from the surface to a depth of about 1 μm in the p-type GaP layer was polished into a mirror surface.

The roughness of the surface of the p-type GaP layer was 0.18 nm by the mirror-like finishing. An n-type GaP transparent substrate to be adhered to the mirror-polished surface of the p-type GaP layer was prepared. Si was added to the transparent substrate for attachment such that the carrier concentration of the transparent substrate was about 2×10¹⁷ cm⁻³ and a single crystal having the plane orientation (111) was used. The diameter of the transparent substrate was 50 millimeters (mm) and the thickness thereof was 250 μm. The surface of the transparent substrate was polished into a mirror surface before the transparent substrate was bonded to the p-type GaP layer and the root mean square (rms) of the transparent substrate was 0.12 nm.

Then, the transparent substrate and the epitaxial wafer were carried in a general semiconductor material attachment apparatus and the apparatus was evacuated to 3×10⁻⁵ Pa.

Then, electrons collided with both the surface of the transparent substrate and the surface of the p-type GaP layer and neutral Ar beams were emitted thereto for three minutes. Then, in the attachment apparatus that was maintained in vacuum, the surfaces of the transparent substrate and the p-type GaP layer overlapped each other and a load was applied such that pressure against each of the surfaces was 50 g/cm². In this way, the transparent substrate and the p-type GaP layer were bonded to each other at a room temperature.

Then, the GaAs substrate and the GaAs buffer layer were selectively removed from the bonded wafer by an ammonia-based etchant. Then, the n-type ohmic electrode was formed as the first electrode on the surface of the contact layer by a vacuum deposition method such that AuGe and a Ni alloy were formed with a thickness of 0.5 μm, Pt was formed with a thickness of 0.2 μm, and Au was formed with a thickness of 1 μm. Then, the electrode was patterned by a general photolithography method, thereby forming the shape of the n-type ohmic electrode.

Then, an epitaxial layer in a region in which the p-type ohmic electrode was formed as the second electrode was selectively removed such that the p-type GaP layer was exposed. The p-type ohmic electrode was formed on the surface of the exposed p-type GaP layer by the vacuum deposition method such that AuBe was formed with a thickness of 0.2 μm and Au was formed with a thickness of 1 μm. Then, a heat treatment was performed at a temperature of 450° C. for 10 minutes to change the electrode into an alloy. In this way, low-resistance p-type and n-type ohmic electrodes were formed.

Then, the third electrode was formed on the lower surface of the transparent substrate. The third electrode included an ITO film that was formed with a thickness of 0.1 μm by a sputtering method, a reflecting layer which was a silver alloy film formed with a thickness of 0.1 μm, a barrier layer which was made of tungsten and was formed with a thickness of 0.1 μm on the reflecting layer, and a connection layer including an Au film that was formed with a thickness of 0.5 μm, an AuSn (eutectic alloy: melting point 283° C.) film that was formed with a thickness of 1 μm, and an Au film that was formed with a thickness of 0.1 μm. Then, the electrode was patterned in a square shape of 200 μm by a general photolithography method. A Schottky contact with small light absorption was formed between the third electrode and the transparent substrate.

Then, a dicing saw was used to cut a region of the transparent substrate in which the third electrode was not formed in a V shape from the rear surface of the transparent substrate such that the angle α of an inclined surface was 70° and the thickness of a vertical surface was 80 μm. Then, the transparent substrate was cut into chips at an interval of 350 μm from the compound semiconductor layer by a dicing saw. A fractured layer and contamination caused by dicing were removed by etching using a mixture of sulfuric acid and hydrogen peroxide. In this way, the light-emitting diode according to Example 1 was manufactured.

100 light-emitting diode lamps in which the light-emitting diode chip according to Example 1 manufactured in the above-mentioned way was mounted on a mounting substrate were mounted. The light-emitting diode lamp was manufactured by heating and connecting the light-emitting diode chip and the mounting substrate with an eutectic die bonder, supporting (mounting) the light-emitting diode chip, connecting the n-type ohmic electrode of the light-emitting diode and the n electrode terminal provided on the surface of the mounting substrate with a gold wire using wire bonding, connecting the p-type ohmic electrode and the p electrode terminal with a gold wire using wire bonding, and sealing the light-emitting diode chip and the mounting substrate with a general epoxy resin.

A current was flowed between the n-type and p-type ohmic electrodes through the n electrode terminal and the p electrode terminal provided on the surface of the mounting substrate. As a result, red light with a dominant wavelength of 620 nm was emitted. A forward voltage (Vf) when a forward current of 20 milliamperes (mA) flowed was about 1.95 volts (V) since the resistance of a bonding interface between the p-type GaP layer of the compound semiconductor layer and the transparent substrate was low and each ohmic electrode had good ohmic characteristics. In addition, emission intensity when the forward current was 20 mA was 800 mcd, which was a high brightness value, since the emission efficiency of light to the outside was high due to the structure of the light-emitting unit with high emission efficiency and the structure of the third electrode having the reflecting layer. There was no mounting defect in the light-emitting diode when 100 light-emitting diode lamps were mounted.

### Example 2

A light-emitting diode according to Example 2 is similar to the light-emitting diode according to Example 1 except that the structure of the third electrode is changed.

The third electrode of the light-emitting diode according to Example 2 included a reflecting layer which was an aluminum film formed with a thickness of 0.2 μm by a sputtering method, a barrier layer that was made of titanium and was formed with a thickness of 0.2 μm on the reflecting layer, and a connection layer including an Au film that was made of a thickness of 0.5 μm, an AuSn (eutectic alloy: melting point 283° C.) film that was formed with a thickness of 1 μm, and an Au film that was formed with a thickness of 0.1 μm. Then, the electrode was patterned in a square shape of 200 μm by a general photolithography method.

100 light-emitting diode lamps each having the light-emitting diode according to Example 2 mounted thereon were manufactured.

A current was flowed between the n-type and p-type ohmic electrodes through the n electrode terminal and the p electrode terminal provided on the surface of the mounting substrate. As a result, red light with a dominant wavelength of 620 nm was emitted. A forward voltage (Vf) when a forward current of 20 milliamperes (mA) flowed was about 2.0 volts (V). In addition, emission intensity when the forward current was 20 mA was 780 mcd. There was no mounting defect in the light-emitting diode when 100 light-emitting diode lamps were mounted.

### Comparative Example 1

A light-emitting diode according to Comparative example 1 was formed in a structure in which the third electrode was not formed in the light-emitting diode according to Example 1. When the light-emitting diode according to Comparative example 1 was mounted on a mounting substrate, Ag paste was used for die bonding. In addition, the amount of Ag paste applied was set such that the thickness of the Ag paste was about 0.5 μm after the Ag paste was applied.

100 light-emitting diode lamps each having the light-emitting diode according to Comparative example 1 mounted thereon were manufactured.

A current was flowed between the n-type and p-type ohmic electrodes through the n electrode terminal and the p electrode terminal provided on the surface of the mounting substrate. As a result, red light with a dominant wavelength of 620 nm was emitted. A forward voltage (Vf) when a forward current of 20 milliamperes (mA) flowed was about 2.0 volts (V). In addition, emission intensity when the forward current was 20 mA was 680 mcd. A mounting defect occurred in two of 100 light-emitting diodes when 100 light-emitting diode lamps were mounted.

### Comparative Example 2

A light-emitting diode according to Comparative example 2 had the same structure as that according to Comparative example 1. When the light-emitting diode according to Comparative example 2 was mounted on a mounting substrate, Ag paste was used for die bonding. The amount of Ag paste for die bonding was 1.5 times more than that in Comparative example 1 and stability was improved during a process of mounting the light-emitting diode lamp.

100 light-emitting diode lamps each having the light-emitting diode according to Comparative example 2 mounted thereon were manufactured.

A current was flowed between the n-type and p-type ohmic electrodes through the n electrode terminal and the p electrode terminal provided on the surface of the mounting substrate. As a result, red light with a dominant wavelength of 620 nm was emitted. A forward voltage (Vf) when a forward current of 20 milliamperes (mA) flowed was about 2.0 volts (V). In addition, emission intensity when the forward current was 20 mA was 590 mcd. There was no mounting defect in the light-emitting diodes when 100 light-emitting diode lamps were mounted.

### Comparative Example 3

A light-emitting diode according to Comparative example 3 had the same structure as that according to Comparative example 1. When the light-emitting diode according to Comparative example 3 was mounted on a mounting substrate, Ag paste was used for die bonding. The amount of Ag paste for die bonding was half that in Comparative example 1 and the brightness of a light-emitting diode lamp was improved.

100 light-emitting diode lamps each having the light-emitting diode according to Comparative example 3 mounted thereon were manufactured.

A current was flowed between the n-type and p-type ohmic electrodes through the n electrode terminal and the p electrode terminal provided on the surface of the mounting substrate. As a result, red light with a dominant wavelength of 620 nm was emitted. A forward voltage (Vf) when a forward current of 20 milliamperes (mA) flowed was about 2.0 volts (V). In addition, emission intensity when the forward current was 20 mA was 730 mcd. A mounting defect occurred in six of 100 light-emitting diodes when 100 light-emitting diode lamps were mounted.

### INDUSTRIAL APPLICABILITY

The light-emitting diode according to the invention can emit red, orange, yellow, or yellowish green light and has high brightness. Therefore, the light-emitting diode according to the invention can be used as various kinds of display lamps.

### REFERENCE SIGNS LIST

1: Light-Emitting Diode
2: Compound Semiconductor Layer
3: Transparent Substrate
3a: Vertical Surface
3b: Inclined Surface
4: n-Type Ohmic Electrode (First Electrode)
5: p-Type Ohmic Electrode (Second Electrode)
6: Third Electrode
7: Light-Emitting Unit
8: p-Type GaP Layer
9: Lower Clad Layer
10: Light-Emitting Layer
11: Upper Clad Layer
13: Reflecting Layer
14: Barrier Layer
15: Connection Layer
15a: Layer Made of Gold (Gold Layer)
15b: Layer Made of Low-Melting-Point Metal (Low-Melting-Point Metal Layer)
16: Oxide Film
17: Semiconductor Substrate
18: Buffer Layer
19: Contact Layer
41: Light-Emitting Diode Lamp
42: Mounting Substrate
43: n Electrode Terminal
44: p Electrode Terminal
45, 46: Gold Wire
47: Epoxy Resin
α: Angle Formed Between Inclined Surface and Plane Parallel to Light-Emitting Surface

1. A light-emitting diode comprising:
a transparent substrate;
a compound semiconductor layer that includes a pn-junction-type light-emitting unit and is bonded to the transparent substrate;
first and second electrodes that are provided on a main light-emitting surface of the light-emitting diode; and
a third electrode that is provided on a surface of the transparent substrate opposite to a bonding surface between the transparent substrate and the compound semiconductor layer.

2. The light-emitting diode according to claim 1,
wherein the third electrode is a Schottky electrode.

3. The light-emitting diode according to claim 1,
wherein the third electrode includes a reflecting layer that has a reflectance of 90% or more with respect to light emitted from the light-emitting surface.

4. The light-emitting diode according to claim 3,
wherein the reflecting layer is made of silver, gold, aluminum, platinum, or an alloy including at least one of the materials.

5. The light-emitting diode according to claim 3,
wherein the third electrode includes an oxide film that is provided between the transparent substrate and the reflecting layer.

6. The light-emitting diode according to claim 5,
wherein the oxide film is a transparent conductive film.

7. The light-emitting diode according to claim 6,
wherein the transparent conductive film is a transparent conductive film (ITO) made of an indium tin oxide.

8. The light-emitting diode according to claim 1,
wherein the third electrode includes a connection layer that is provided on a side opposite to the surface which comes into contact with the transparent substrate.

9. The light-emitting diode according to claim 8,
wherein the connection layer is made of eutectic metal with a melting point of less than 400° C.

10. The light-emitting diode according to claim 8,
wherein the third electrode includes a high-melting-point barrier metal that is provided between the reflecting layer and the connection layer and has a melting point of 2000° C. or more.

11. The light-emitting diode according to claim 10,
wherein the high-melting-point barrier metal includes at least one selected from the group consisting of tungsten, molybdenum, titanium, platinum, chromium, and tantalum.

12. The light-emitting diode according to claim 1,
wherein the light-emitting unit includes a light-emitting layer that is made of a material represented by a composition formula (Al_{X}Ga_{1-X})_{Y}In_{1-Y}P (0≦X≦1, 0<Y≦1).

13. The light-emitting diode according to claim 1,
wherein the first and second electrodes are ohmic electrodes.

14. The light-emitting diode according to claim 1,
wherein the transparent substrate is made of GaP.

15. The light-emitting diode according to claim 1,
wherein a side surface of the transparent substrate includes a vertical surface that is close to the compound semiconductor layer and is substantially vertical to the light-emitting surface and an inclined surface that is distanced away from the compound semiconductor layer and is inclined inward with respect to the light-emitting surface.

16. The light-emitting diode according to claim 1, further comprising:
a high-resistivity layer that is provided between the compound semiconductor layer and the transparent substrate and has a resistance more than that of the transparent substrate.

17. A light-emitting diode lamp comprising:
the light-emitting diode according to claim 1,
wherein the first or second electrode provided above the light-emitting unit of the light-emitting diode and the third electrode are connected to each other so as to have substantially the same potential.
